(19) United States
(12) Patent Application Publication
(10) Pub. No.: US 2024/0018372 A1
(43) Pub. Date: Jan. 18, 2024

(54) COMPOSITION, FUNCTIONAL LAYER, AND DISPLAY MODULE

(71) Applicant: KunShan Go-Visionox Opto-Electronics Co., Ltd, Kunshan (CN)

(72) Inventors: Xiujian ZHU, Kunshan (CN); Renjie LIU, Kunshan (CN)

(73) Assignee: KunShan Go-Visionox Opto-Electronics Co., Ltd, Kunshan (CN)

(21) Appl. No.: 18/474,328

(22) Filed: Sep. 26, 2023

Related U.S. Application Data
(63) Continuation of application No. PCT/CN2022/138568, filed on Dec. 13, 2022.

(30) Foreign Application Priority Data
May 5, 2022 (CN) 2022104919522
Nov. 24, 2022 (CN) 2022114844058

(51) Int. Cl. C09D 7/65; C09D 133/02; C09D 4/00; C09D 133/14; C09D 133/08

(52) U.S. Cl. CPC C09D 7/65; C09D 133/02; C09D 4/00; C09D 133/14; C09D 133/08; H10K 59/10

(57) ABSTRACT

A composition, a functional layer, and a display module, where the composition includes, in parts by mass, 50-70 parts of a (methyl) acrylic compound, 30-50 parts of an additive, 30-50 parts of a reactive diluent, and 0-10 parts of an auxiliary agent; the additive includes a first polyolefin-polyisoprene-second polyolefin block copolymer and/or a derivative of the first polyolefin-polyisoprene-second polyolefin block copolymer. The composition has a low dielectric constant, so it can be used as a medium to effectively shield static electricity so as to overcome related defects caused by static electricity.

### CROSS-REFERENCE TO RELATED APPLICATIONS

The present application is a continuation of International Application No. PCT/CN2022/138568, filed on Dec. 13, 2022, which claims priority to Chinese Patent Application No. 202210491952.2, filed on May 5, 2022, and Chinese Patent Application No. 202211484405.8, filed on Nov. 24, 2022. All of the aforementioned patent applications are hereby incorporated by reference in their entireties.

### TECHNICAL FIELD

The present application relates to a composition, a functional layer and a display module, and belongs to the field of display technology.

### BACKGROUND

With the development of display technology, people have put forward higher requirements for various performances of display devices. Flexible display screen, due to the characteristic of being able to bend arbitrarily, can provide superior visual enjoyment when unfolded, and has the advantage of portability and small size when stored. As a result, the flexible display screen has gradually become a major trend in the development of electronic products.

However, during the use of the flexible display screen, the accumulation of electrostatic charges and discharge process thereof will cause damage to the display screen to varying degrees, seriously affecting the normal display function of the display screen, especially the green screen phenomenon of the display screen caused by static electricity is prominent.

### SUMMARY

The present application provides a composition, a functional layer, and a display module, which can overcome related defects caused by static electricity.

The present application provides a composition, which includes in parts by mass, 50-70 parts of a (methyl) acrylic compound, 30-50 parts of an additive, 30-50 parts of a reactive diluent, and 0-10 parts of an auxiliary agent;
the additive includes a first polyolefin-polyisoprene-second polyolefin block copolymer and/or derivative of the first polyolefin-polyisoprene-second polyolefin block copolymer.

The present application also provides a functional layer, raw material of which includes the above-mentioned composition.

The present application also provides a display module, which includes the above-mentioned functional layer.

The composition with specific components provided by the present application can exhibit a relatively low dielectric constant, and thus has an excellent shielding effect on electrostatic charges. The shielding effect is beneficial to reducing the accumulation of electrostatic charges on the screen, thereby improving the display effect of the display module by inhibiting the damage to the thin film transistor caused by electrostatic charges, effectively reducing the probability of green screen phenomenon of the display module, and improving the manufacturing yield of the display module.

### DETAILED DESCRIPTION OF EMBODIMENTS

In order to make the objective, technical solution and advantages of the present application more clear, the technical solutions in embodiments of the present application will be described clearly and completely in the following. Obviously, the described embodiments are a part of embodiments of the present application, but not all embodiments. Based on the embodiments in the present application, all other embodiments obtained by ordinary skilled in the art without creative work belong to the protection scope of the present application.

In a first aspect, the present application provides a composition, which includes in parts by mass: 50-70 parts of a (methyl) acrylic compound, 30-50 parts of an additive, 30-50 parts of a reactive diluent, and 0-10 parts of an auxiliary agent;
the additive includes a first polyolefin-polyisoprene-second polyolefin block copolymer and/or derivative of the first polyolefin-polyisoprene-second polyolefin block copolymer.

The (methyl) acrylic compound includes at least one of (methyl) acrylic acid, polyurethane (methyl) acrylic acid, polyester (methyl) acrylic acid, polyether (methyl) acrylic acid, and epoxy (methyl) acrylic acid. The first polyolefin-polyisoprene-second polyolefin block copolymer refers to two polyolefin segments linked via polyisoprene, and specific monomers in the first polyolefin and the second polyolefin are not limited in the present application. The first polyolefin and the second polyolefin are polymers obtained by polymerization of respective olefin monomers in the first polyolefin and the second polyolefin which are independently polymerized, and each of the first polyolefin and the second polyolefin independently includes, for example, an ethylene homopolymer segment, a propylene homopolymer segment or an ethylene-propylene copolymer segment. In the present application, the molecular weights of the first polyolefin and the second polyolefin are not limited, and the molecular weights of them can be the same or different. Meanwhile, the molecular weight of the first polyolefin-polyisoprene-second polyolefin block copolymer is not limited, and the weight average molecular weight of the block copolymer is generally above 100,000.

The additive in the present application can be not only the first polyolefin-polyisoprene-second polyolefin block copolymer, but also derivative of the first polyolefin-polyisoprene-second polyolefin block copolymer, or a composition of the first polyolefin-polyisoprene-second polyolefin block copolymer and derivative of the first polyolefin-polyisoprene-second polyolefin block copolymer. When the additive is the composition of the first polyolefin-polyisoprene-second polyolefin block copolymer and derivative of the first polyolefin-polyisoprene-second polyolefin block copolymer, the mass ratio of the first polyolefin-polyisoprene-second polyolefin block copolymer to derivative of the first polyolefin-polyisoprene-second polyolefin block copolymer is not limited in the present application. The derivative of the first polyolefin-polyisoprene-second polyolefin block copolymer described in the present application refers to a product obtained after the first polyolefin and/or the second polyolefin is substituted with a substituent group, and the substituent group for example can be C1-C10 alkyl (including linear alkyl, branched alkyl and cycloalkyl), halogen, hydroxyl, nitro, amino, cyano, silyl, siloxy and the like.

The reactive diluent is mainly a (methyl) acrylate compound, such as includes at least one of (methyl) ethyl acrylate, (methyl) butyl acrylate, (methyl) methyl acrylate, (methyl) hydroxyl acrylate, diol (methyl) ethyl acrylate, diol (methyl) butyl acrylate, diol (methyl) methyl acrylate, diol (methyl) hydroxy acrylate, alkoxy (methyl) ethyl acrylate, alkoxy (methyl) butyl acrylate, alkoxy (methyl) methyl acrylate, and alkoxy (methyl) hydroxyl acrylate.

In addition, the auxiliary agent in the composition mainly includes one or more of a defoaming agent, a leveling agent, and a polymerization inhibitor.

The main function of the defoaming agent is to inhibit, reduce and eliminate bubbles in the composition. As long as the defoaming agent can meet the above performance requirements, the selection of the defoaming agent is not specifically limited in the present application, which for example can be an alcohol compound.

The function of the polymerization inhibitor is mainly to improve the storage stability of the composition. The polymerization inhibitor may include, for example, at least one of hydroquinone, benzoquinone, p-hydroxyanisole, 2-tert-butylhydroquinone, 2,5-di-tert-butylhydroquinone, tris (N-nitroso-N-phenylhydroxylamine) aluminum salt (polymerization inhibitor 510) and the like.

The leveling agent is mainly used to improve the fluidity of the composition and the wettability to a substrate. As long as the leveling agent can meet the above performance requirements, the present application does not specifically limit the selection of the leveling agent, which for example can be an organic silicon resin.

In the present application, components with different polarities are combined according to a certain proportion, and finally the composition shows a relatively low dielectric constant (the dielectric constant of the composition is not higher than 3.1, and finally the dielectric constant of a functional layer including the composition is not higher than 2.5), so that the composition can be used in scenes having the requirement of preventing electrostatic inhalation to effectively shield static electricity. The present application does not limit specific application mode of the composition, which can be used alone, or which as a component having antistatic function can be mixed with other functional components. When mixed with other functional components, it is preferred to mix a (methyl) acrylic compound, an additive, a reactive diluent and an auxiliary agent in a defined mass ratio to obtain a composition, and then perform a next mixing of the composition with other functional layer components. Preferably, the (methyl) acrylic compound is 55-65 parts, the additive is 35-45 parts, the reactive diluent is 35-45 parts and the auxiliary agent is 3-7 parts. Optionally, the (methyl) acrylic compound can be 51, 53, 54, 56, 57, 58, 61, 63, 64, 67 or 68 parts, the additive can be 31, 32, 33, 34, 37, 38, 42, 43 or 47 parts, the reactive diluent can be 32, 33, 34, 36, 38, 41, 43 or 48 parts, and the auxiliary agent can be 1, 2, 3, 6, 7 or 9 parts.

In addition, there is no special limitation on the addition order of respective components of the composition, as long as the components can be evenly mixed.

Further, when the weight average molecular weight of the additive is 100,000-300,000, the dielectric constant of the composition will be further reduced, which is more conducive to shielding electrostatic charge. Optionally, the weight average molecular weight of the additive is 100,000, 120,000, 130,000, 150,000, 180,000, 200,000, 220,000, 240,000, 250,000, 270,000, 290,000 or 300,000.

In a specific embodiment, the additive includes at least one of a polystyrene-polyisoprene-polystyrene block copolymer and/or derivative of the polystyrene-polyisoprene-polystyrene block copolymer, a polyethylene-polyisoprene-polyethylene block copolymer and/or derivative of the polyethylene-polyisoprene-polyethylene block copolymer, and a polypropylene-polyisoprene-polyethylene block copolymer and/or derivative of the polypropylene-polyisoprene-polyethylene block copolymer. The polystyrene-polyisoprene-polystyrene block copolymer and/or derivative of the polystyrene-polyisoprene-polystyrene block copolymer refer to a polystyrene-polyisoprene-polystyrene block copolymer, a derivative of the polystyrene-polyisoprene-polystyrene block copolymer, or a mixture of the polystyrene-polyisoprene-polystyrene block copolymer and the derivative of the polystyrene-polyisoprene-polystyrene block copolymer. The polyethylene-polyisoprene-polyethylene block copolymer and/or derivative of the polyethylene-polyisoprene-polyethylene block copolymer refer to a polyethylene-polyisoprene-polyethylene block copolymer, a derivative of the polyethylene-polyisoprene-polyethylene block copolymer, or a mixture of the polyethylene-polyisoprene-polyethylene block copolymer and the derivative of the polyethylene-polyisoprene-polyethylene block copolymer. The polypropylene-polyisoprene-polyethylene block copolymer and/or derivative of the polypropylene-polyisoprene-polyethylene block copolymer refer to a polypropylene-polyisoprene-polyethylene block copolymer, a derivative of the polypropylene-polyisoprene-polyethylene block copolymer, or a mixture of the polypropylene-polyisoprene-polyethylene block copolymer and the derivative of the polypropylene-polyisoprene-polyethylene block copolymer.

Further, the additive is a polystyrene-polyisoprene-polystyrene block copolymer and/or derivative of the polystyrene-polyisoprene-polystyrene block copolymer. Where, the polystyrene segment is 60 wt %-85 wt % and the polyisoprene segment is 15 wt %-40 wt %.

The composition of the present application may also include an initiator. The inventors find that when the initiator is included in the composition, the dielectric constant can be further reduced by initiating the polymerization of the composition. Specifically, the change rate of the dielectric constant before and after initiation is generally not less than 20%, and even can be as high as 75%. The difference of the change rate is not only related to the specific selection of the (methyl) acrylic compound, the additive, and the reactive diluent, but also related to conditional parameters of polymerization reaction, so it can be adjusted according to requirements in the application process.

In order to ensure efficient initiation and avoid unnecessary influence of temperature on each component in the composition, a photoinitiator is preferably selected in the present application. When it is necessary to initiate the system, it is only necessary to expose the composition including the initiator to UV light for irradiation. Generally, the irradiation time is about 20 s. It should be noted that in order to avoid premature initiation, it is necessary to keep the composition including an initiator in a dark state when it is in the transportation and storage stage.

For example, the photoinitiator includes one or more of 1-hydroxycyclohexyl phenyl ketone, 2-benzyl-2-dimethylamino-1-(4-morpholinophenyl) butanone, 2-benzyl-2-dimethyl-1-(4-morpholinophenyl) butanone, benzophenone, 4-phenylbenzophenone, benzoin diethyl ether, 2-chloro thioxanthone, 2,4-diethyl thioxanthone.

It is worth mentioning that when the composition is polymerized by including an initiator to further reduce the dielectric constant, the polymerization of the composition is also beneficial to further reduce the contents of small molecular radicals in the system, thus making the performance of inhibiting electrostatic adsorption more remarkable.

In a second aspect, the present application provides a functional layer, and the raw material of the functional layer includes the composition of the first aspect.

In one embodiment, the functional layer includes the composition, that is, the functional layer includes 50-70 parts of a (methyl) acrylic compound, 30-50 parts of an additive, 30-50 parts of a reactive diluent and 0-10 parts of an auxiliary agent. It can be understood that the functional layer may include other components besides the composition. As mentioned above, because the composition has a low dielectric constant, the functional layer can be used as a film layer to prevent electrostatic injection.

In another embodiment, the functional layer is obtained by polymerization of a raw material system including the composition of the first aspect. As mentioned above, after the composition is initiated for polymerization, not only its dielectric constant can be further reduced, but also the contents of small molecular radicals in the system will be significantly reduced, so the functional layer's performance of preventing electrostatic injection will be more prominent.

The implementation of specific functional layers can be selected according to requirements of present application scenarios.

During preparation, the raw material system including the composition can be coated on a substrate and peeled off from the substrate after forming, thus obtaining the functional layer. Alternatively, after the raw material system including the composition is initiated for polymerization, the polymerized system is coated on a substrate and then peeled off from the substrate, thereby obtaining the functional layer.

As a preferred embodiment, the functional layer of the present application includes a polymer which is obtained by polymerizing at least a (methyl) acrylic compound, an additive, and a reactive diluent that are used as monomers. The additive refers to the first polyolefin-polyisoprene-second polyolefin block copolymer and/or the derivative of the first polyolefin-polyisoprene-second polyolefin block copolymer.

It can be understood that the above polymer can be a copolymer obtained by mutual copolymerization of three monomers, a block copolymer formed by the combination of homopolymerized segments of respective three monomers, or a block composition formed by the combination of the above copolymer and the block copolymer. More specifically, the copolymer obtained by mutual copolymerization of three monomers refers to a copolymer in which a (methyl) acrylic compound, an additive and an reactive diluent are polymerized with each other, and the block copolymer formed by the combination of homopolymerized segments of respective three monomers refers to a block polymer including a homopolymerized segment of a (methyl) acrylic compound, a homopolymerized segment of an additive, and a homopolymerized segment of an reactive diluent.

The functional layer is obtained by the polymerization of the foregoing composition, so that the functional layer not only has a low dielectric constant, but also has low contents of small molecular radicals, therefore, under the synergistic effect of the two, the functional layer can be used as a film element for effectively preventing electrostatic adsorption to apply in various devices. It should be noted that the small molecular radicals specifically refer to hydroxyl and carboxyl groups in the present application.

Further, the functional layer of the present application has a dielectric constant of 1.5-2.5, an acid value of 0-1.4 and a hydroxyl value of 0-3.9. Where, the acid value and hydroxyl value are used to characterize the contents of carboxyl group and hydroxyl group in the functional layer respectively. By limiting the dielectric constant, acid value and hydroxyl value of the functional layer, the electrostatic shielding performance of the functional layer can be significantly improved. In a specific application process, the functional layer with the above parameters can be realized by controlling components of the composition. In one embodiment, the composition includes, in parts by mass, 50-70 parts of acrylic acid, 30-50 parts of a polystyrene-polyisoprene-polyethylene block copolymer, 30-50 parts of a reactive diluent, 1-10 parts of a photoinitiator, and 1-5 parts of an auxiliary agent. Optionally, in the polystyrene-polyisoprene-polyethylene block copolymer, the polystyrene is 60 wt %-85 wt % and the polyisoprene is 15 wt %-40 wt %.

Furthermore, the functional layer has a dielectric constant of 1.5-2.0, an acid value of 0-1 and a hydroxyl value of 0-3. Optionally, the dielectric constant of the functional layer is 1.5, 1.6, 1.7, 1.8, 2.1, 2.3 or 2.4, the acid value is 0.2, 0.3, 0.4, 0.7, 0.8, 0.9, 1.1, 1.2 or 1.3, and the hydroxyl value is 0.5, 1.0, 1.2, 1.4, 1.5, 1.7, 1.8, 2.0, 2.2, 2.4, 2.5, 2.8, 3.0, 3.3, 3.5, 3.7 or 3.8.

In other embodiments of the present application, by further controlling components of the composition, the mechanical properties of the functional layer can also be improved, specifically, the mechanical properties include storage modulus and adhesion force. The inventors find that when the storage modulus of the functional layer is 164 kPa-180 kPa and the adhesive force is 1000 gf-2100 gf; preferably, the storage modulus of the functional layer is 170 kPa-172 kPa and the adhesive force is 1900 gf-2000 gf, the problems of internal tearing and bubble generation in the functional layer during the application process can be avoided. Optionally, the functional layer has a storage modulus of is 164 kPa, 165 kPa, 168 kPa, 170 kPa, 172 kPa, 175 kPa, 177 kPa or 180 kPa, and has an adhesion force of 1000 gf, 1100 gf, 1200 gf, 1300 gf, 1400 gf, 1500 gf, 1600 gf, 1700 gf, 1800 gf, 1900 gf, 2000 gf or 2100 gf.

The present application does not limit the preparation method of the functional layer, and in one embodiment, the functional layer is obtained according to the following preparation method:
subjecting a raw material system including the composition to polymerization to obtain the functional layer.

The raw material system at least includes the foregoing composition, so that it can be guaranteed that the functional layer has a lower dielectric constant.

When other components are included in the raw material system, the composition can be initiated for polymerization at first, then the polymer can be mixed with other components. Alternatively, the composition can be mixed with other components, then the raw material system is initiated for polymerization.

It can be understood that the addition order of respective components in the composition is related to the final polymer structure. The present application does not limit the structure of the final polymer as long as the raw material system including the composition is polymerized in a specific implementation process of the present application. For example, a (methyl) acrylic compound can be homopolymerized to form a homopolymerized segment of the (methyl) acrylic compound (denoted by A), and then an additive can be added for homopolymerization to obtain a homopolymerized segment of the additive (denoted by B), in which case the polymer is a block copolymer including A-B; alternatively, a part of a (methyl) acrylic compound can be homopolymerized to form a homopolymerized segment of the (methyl) acrylic compound (denoted by A), and then the remaining (methyl) acrylic compound and an additive are added for copolymerization to obtain a copolymerized segment of the (methyl) acrylic compound and the additive (denoted by C), and the polymer is a block copolymer including A-C; or a (methyl) acrylic compound and an additive can be added at the same time for copolymerization, and at this time, the polymer is a copolymer in which the (methyl) acrylic compound and the additive as monomers are copolymerized.

In a third aspect, the present application also provides a display module including the functional layer of the second aspect.

Because the functional layer has electrostatic shielding function, the functional layer can reduce the accumulation of static electricity in the display module and avoid the influence of static electricity on the reliability and display quality of the display module.

In a specific embodiment, the display module includes a display panel and a support layer located at a non-light-emitting side of the display panel, and the functional layer is located between the display panel and the support layer.

Specifically, the display panel has a light-emitting side and a non-light-emitting side that are oppositely arranged, and the support layer arranged at the non-light-emitting side is mainly used for supporting and protecting the display panel, and the support layer is generally made of metal foil, so that the external impact force received by the display module in the application process can be effectively buffered. In some embodiments, a side of the support layer away from the display panel is also provided with a protective film, and the protective film is attached to a surface of the support layer to protect the display module that is in operation, and can be removed when protection is not needed.

During the application or detection process of the display module, no matter a copper bar friction test to the display module or the removal of the protective film, a large amount of electrostatic charges will be injected into the display module, and some electrostatic charges will directly enter the inside of the display panel along the support layer, which will affect the electrical properties of a thin film transistor TFT of the display panel through back-channel-effect, thus leading to abnormal display, especially green screen phenomenon on the display panel. In the present application, by arranging the functional layer between the support layer and the display panel, the functional layer can be used as an electrostatic barrier to prevent electrostatic charges from entering the display panel through the support layer, and the display effect of the display panel is improved by avoiding the electrical damage of the thin film transistor TFT, thereby not only improving the yield of the display module, but also significantly improving user satisfaction.

In a specific application process, the thickness of the functional layer is 5-25 μm. Optionally, the thickness of the functional layer is 5, 10, 15, 20 or 25 μm.

The functional layer, in addition to having the above-mentioned function of shielding electrostatic charges, can also be used as an adhesive layer between the support layer and the display panel. Of course, in order to further ensure the adhesive effect, other optical adhesive layers or pressure-sensitive adhesive layers that are common in this field can be arranged between the functional layer and the support layer and between the functional layer and the display panel.

The present application does not limit the specific composition of the display panel, but generally it includes a screen body and a substrate which are arranged in a stacked manner, and the functional layer is located between the substrate and the support layer. The present application does not limit the display type of the screen body, for example, it can be an OLED display screen including at least a cathode layer, a luminescent layer and an anode layer. The substrate is located at a non-light emitting side of the screen body and is mainly used to protect the screen body and prevent the screen body from being damaged during operation or use of the screen body. Generally, the substrate is made of a flexible material, such as polyimide.

In addition, at the light-emitting side of the display panel, a polarizer, an optical adhesive layer, and a cover plate which are arranged in a stacked manner are included in a sequence gradually away from the display panel. The polarizer is used to adjust the light emitted from the display panel to improve display quality. The cover plate is used for sealing and protecting the display panel to avoid damage from the outside. The optical adhesive layer has light transmittance, which is used for fixing and bonding the cover plate and polarizer.

In the present application, the thicknesses of respective film layers constituting the display module are not particularly limited. Specifically, the thicknesses of the screen body, the substrate, the support layer, the cover plate, the polarizer, and respective adhesive layers are consistent with the existing thickness in the field.

Because the display module of the present application has excellent display effect, electronic devices (including but not limited to mobile phones, televisions, computers, etc.) including the display module of the present application also have excellent display effect, and the occurrence of green screen phenomenon caused by electrostatic adsorption can be greatly reduced in the application process.

In the following, the present application will be introduced in more detail through specific examples.

Additives in all examples are purchased from Cotten, USA.

### Example 1a

A composition of the present example includes:
a (methyl) acrylic compound: 65 g of methacrylic acid;
an additive: 46 g of polyethylene-polyisoprene-polyethylene block copolymer with weight average molecular weight of 200,000 (70 wt %-75 wt % of polyethylene and 25 wt %-30 wt % of polyisoprene);
a reactive diluent: 35 g of ethyl acrylate.

### Example 1b

A method for preparing a functional layer in the present example includes the following steps:
adding 3 g of a photoinitiator, i.e. 1-hydroxycyclohexyl phenyl ketone to the composition of Example 1a, then coating the system added with the initiator onto a surface of a PET substrate and performing UV illumination, then waiting the system to be cured, to obtain the functional layer.

### Example 2a

A composition of the present example includes:
a (methyl) acrylic compound: 67 g of polyurethane acrylic acid;
an additive: 43 g of polypropylene-polyisoprene-polyethylene block copolymer with weight average molecular weight of 210,000 (80 wt %-85 wt % of polyethylene and 15 wt %-20 wt % of polyisoprene);
a reactive diluent: 34 g of alkoxy acrylate.

### Example 2b

A method for preparing a functional layer in the present example includes the following steps:
adding 3 g of a photoinitiator, i.e. 1-hydroxycyclohexyl phenyl ketone to the composition of Example 2a, then coating the system added with the initiator onto a surface of a PET substrate and performing UV illumination, then waiting the system to be cured, to obtain the functional layer.

### Example 3a

A composition of the present example includes:
a (methyl) acrylic compound: 66 g of polyester acrylic acid;
an additive: 38 g of polypropylene-polyisoprene-polyethylene block copolymer with weight average molecular weight of 210,000 (75 wt %-80 wt % of polyethylene and 20 wt %-25 wt % of polyisoprene);
a reactive diluent: 34 g of butyl acrylate.

### Example 3b

A method for preparing a functional layer in the present example includes the following steps:
adding 3 g of a photoinitiator, i.e. 1-hydroxycyclohexyl phenyl ketone to the composition of Example 3a, then coating the system added with the initiator onto a surface of a PET substrate and performing UV illumination, then waiting the system to be cured, to obtain the functional layer.

### Example 4a

A composition of the present example includes:
a (methyl) acrylic compound: 60 g of polyether acrylic acid;
an additive: 38 g of polypropylene-polyisoprene-polyethylene block copolymer with weight average molecular weight of 210,000 (75 wt %-80 wt % of polyethylene and 20 wt %-25 wt % of polyisoprene);
a reactive diluent: 40 g of methyl acrylate.

### Example 4b

A method for preparing a functional layer in the present example includes the following steps:
adding 3 g of a photoinitiator, i.e. 1-hydroxycyclohexyl phenyl ketone to the composition of Example 4a, then coating the system added with the initiator onto a surface of a PET substrate and performing UV illumination, then waiting the system to be cured, to obtain the functional layer.

### Example 5a

A composition 5a of the present example is basically the same as that of example 1a, except that the weight average molecular weight of the polyethylene-polyisoprene-polyethylene block copolymer of the present example is 80,000.

### Example 5b

A method for preparing a functional layer in the present example includes the following steps:
adding 3 g of a photoinitiator, i.e. 1-hydroxycyclohexyl phenyl ketone to the composition of Example 5a, then coating the system added with the initiator onto a surface of a PET substrate and performing UV illumination, then waiting the system to be cured, to obtain the functional layer.

### Example 6a

A composition 6a of the present example is basically the same as that of example 1a, except that the weight average molecular weight of the polyethylene-polyisoprene-polyethylene block copolymer of the present embodiment is 320,000.

### Example 6b

A method for preparing a functional layer in the present example includes the following steps:
adding 3 g of a photoinitiator, i.e. 1-hydroxycyclohexyl phenyl ketone to the composition of Example 6a, then coating the system added with the initiator onto a surface of a PET substrate and performing UV illumination, then waiting the system to be cured, to obtain the functional layer.

### Example 7a

A composition of the present example includes:
a (methyl) acrylic compound: 50 g of polyether acrylic acid;
an additive: 30 g of polypropylene-polyisoprene-polyethylene block copolymer with weight average molecular weight of 24 w (65 wt %-70 wt % of polyethylene and 30 wt %-35 wt % of polyisoprene);
a reactive diluent: 47 g of methyl acrylate;
an auxiliary agent: 1 g of ethylene glycol and 2 g of polydimethylsiloxane.

### Example 7b

A method for preparing a functional layer in the present example includes the following steps:
adding 3 g of a photoinitiator, i.e. 1-hydroxycyclohexyl phenyl ketone to the composition of Example 7a, then coating the system added with the initiator onto a surface of a PET substrate and performing UV illumination, then waiting the system to be cured, to obtain the functional layer.

### Example 8

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 65 g of methacrylic acid;
an additive: 46 g of polyethylene-polyisoprene-polyethylene block copolymer with weight average molecular weight of 200,000 (70 wt %-75 wt % of polyethylene and 25 wt %-30 wt % of polyisoprene);
a reactive diluent: 35 g of ethyl acrylate.

### Example 9

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 67 g of polyurethane acrylic acid;
an additive: 43 g of polypropylene-polyisoprene-polyethylene block copolymer with weight average molecular weight of 210,000 (80 wt %-85 wt % of polyethylene and 15 wt %-20 wt % of polyisoprene);
a reactive diluent: 34 g of alkoxy acrylate.

### Example 10

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 66 g of polyester acrylic acid;
an additive: 38 g of polypropylene-polyisoprene-polyethylene block copolymer with weight average molecular weight of 210,000 (75 wt %-80 wt % of polyethylene and 20 wt %-25 wt % of polyisoprene);
a reactive diluent: 34 g of butyl acrylate.

### Example 11

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 60 g of polyether acrylic acid;
an additive: 38 g of polypropylene-polyisoprene-polyethylene block copolymer with weight average molecular weight of 210,000 (75 wt %-80 wt % of polyethylene and 20 wt %-25 wt % of polyisoprene);
a reactive diluent: 40 g of methyl acrylate.

### Example 12

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 65 g of methacrylic acid;
an additive: 46 g of polyethylene-polyisoprene-polyethylene block copolymer with weight average molecular weight of 80,000 (70 wt %-75 wt % of polyethylene and 25 wt %-30 wt % of polyisoprene);
a reactive diluent: 35 g of ethyl acrylate.

### Example 13

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 65 g of methacrylic acid;
an additive: 46 g of polyethylene-polyisoprene-polyethylene block copolymer with weight average molecular weight of 320,000 (70 wt %-75 wt % of polyethylene and 25 wt %-30 wt % of polyisoprene);
a reactive diluent: 35 g of ethyl acrylate.

### Example 14

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 50 g of polyether acrylic acid;
an additive: 30 g of polypropylene-polyisoprene-polyethylene block copolymer with weight average molecular weight of 240,000 (65 wt %-70 wt % of polyethylene and 30 wt %-35 wt % of polyisoprene);
a reactive diluent: 47 g of methyl acrylate;
an auxiliary agent: 1 g of ethylene glycol and 2 g of polydimethylsiloxane.

### Example 15a

A composition of the present example includes: a (methyl) acrylic compound: 63 g of methacrylic acid;
an additive: 44 g of polystyrene-polyisoprene-polystyrene block copolymer with weight average molecular weight of 210,000 (70 wt %-75 wt % of polystyrene and 25 wt %-30 wt % of polyisoprene);
a reactive diluent: 37 g of ethyl acrylate.

### Example 15b

A method for preparing a functional layer in the present example includes the following steps:
adding 3 g of a photoinitiator, i.e. 1-hydroxycyclohexyl phenyl ketone to the composition of Example 15a, then coating the system added with the initiator onto a surface of a PET substrate and performing UV illumination, then waiting the system to be cured, to obtain the functional layer.

### Example 16a

A composition of the present example includes:
a (methyl) acrylic compound: 67 g of polyurethane acrylic acid;
an additive: 43 g of polystyrene-polyisoprene-polystyrene block copolymer with weight average molecular weight of 210,000 (80 wt %-85 wt % of polystyrene and 15 wt %-20 wt % of polyisoprene);
a reactive diluent: 34 g of alkoxy acrylate.

### Example 16b

A method for preparing a functional layer in the present example includes the following steps:
adding 3 g of a photoinitiator, i.e. 1-hydroxycyclohexyl phenyl ketone to the composition of Example 16a, then coating the system added with the initiator onto a surface of a PET substrate and performing UV illumination, then waiting the system to be cured, to obtain the functional layer.

### Example 17a

A composition of the present example includes:
a (methyl) acrylic compound: 66 g of polyester acrylic acid;
an additive: 38 g of polystyrene-polyisoprene-polystyrene block copolymer with weight average molecular weight of 210,000 (75 wt %-80 wt % of polystyrene and 20 wt %-25 wt % of polyisoprene);
a reactive diluent: 34 g of butyl acrylate.

### Example 17b

A method for preparing a functional layer in the present example includes the following steps:
adding 3 g of a photoinitiator, i.e. 1-hydroxycyclohexyl phenyl ketone to the composition of Example 17a, then coating the system added with the initiator onto a surface of a PET substrate and performing UV illumination, then waiting the system to be cured, to obtain the functional layer.

### Example 18a

A composition of the present example includes:
a (methyl) acrylic compound: 60 g of polyether acrylic acid;
an additive: 38 g of polystyrene-polyisoprene-polystyrene block copolymer with weight average molecular weight of 210,000 (75 wt %-80 wt % of polystyrene and 20 wt %-25 wt % of polyisoprene);
a reactive diluent: 40 g of methyl acrylate.

### Example 18b

A method for preparing a functional layer in the present example includes the following steps:
adding 3 g of a photoinitiator, i.e. 1-hydroxycyclohexyl phenyl ketone to the composition of Example 18a, then coating the system added with the initiator onto a surface of a PET substrate and performing UV illumination, then waiting the system to be cured, to obtain the functional layer.

### Example 19a

A composition 19a of the present example is basically the same as that of Example 15a, except that the weight average molecular weight of the polystyrene-polyisoprene-polystyrene block copolymer of the present example is 60,000.

### Example 19b

A method for preparing a functional layer in the present example includes the following steps:
adding 3 g of a photoinitiator, i.e. 1-hydroxycyclohexyl phenyl ketone to the composition of Example 19a, then coating the system added with the initiator onto a surface of a PET substrate and performing UV illumination, then waiting the system to be cured, to obtain the functional layer.

### Example 20a

A composition 20a of the present example is basically the same as that of Example 15a, except that the weight average molecular weight of the polystyrene-polyisoprene-polystyrene block copolymer of the present example is 330,000.

### Example 20b

A method for preparing a functional layer in the present example includes the following steps:
adding 3 g of a photoinitiator, i.e. 1-hydroxycyclohexyl phenyl ketone to the composition of Example 20a, then coating the system added with the initiator onto a surface of a PET substrate and performing UV illumination, then waiting the system to be cured, to obtain the functional layer.

### Example 21a

A composition of the present example includes:
a (methyl) acrylic compound: 55 g polyether acrylic acid;
an additive: 34 g of polystyrene-polyisoprene-polystyrene block copolymer with weight average molecular weight of 250,000 (65 wt %-70 wt % of polystyrene and 30 wt %-35 wt % of polyisoprene);
a reactive diluent: 49 g of methyl acrylate;
an auxiliary agent: 1 g of ethylene glycol and 2 g of polydimethylsiloxane.

### Example 21b

A method for preparing a functional layer in the present example includes the following steps:
adding 3 g of a photoinitiator, i.e. 1-hydroxycyclohexyl phenyl ketone to the composition of Example 21a, then coating the system added with the initiator onto a surface of a PET substrate and performing UV illumination, then waiting the system to be cured, to obtain the functional layer.

### Example 22

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition of Example 15a, then coating the system added with the initiator onto a surface of a PET substrate and performing UV illumination, then waiting the system to be cured, to obtain the functional layer.

Components of the above composition in the present example include:
(methyl) acrylic compound: 63 g of methacrylic acid;
an additive: 44 g of polystyrene-polyisoprene-polystyrene block copolymer with weight average molecular weight of 210,000 (70 wt %-75 wt % of polystyrene and 25 wt %-30 wt % of polyisoprene);
a reactive diluent: 37 g of ethyl acrylate.

### Example 23

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 67 g of polyurethane acrylic acid;
an additive: 43 g of polystyrene-polyisoprene-polystyrene block copolymer with weight average molecular weight of 210,000 (80 wt %-85 wt % of polystyrene and 15 wt %-20 wt % of polyisoprene);
a reactive diluent: 34 g of alkoxy acrylate.

### Example 24

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 66 g of polyester acrylic acid;
an additive: 38 g of polystyrene-polyisoprene-polystyrene block copolymer with weight average molecular weight of 210,000 (75 wt %-80 wt % of polystyrene and 20 wt %-25 wt % of polyisoprene);
a reactive diluent: 34 g of butyl acrylate.

### Example 25

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 60 g of polyether acrylic acid;
an additive: 38 g of polystyrene-polyisoprene-polystyrene block copolymer with weight average molecular weight of 210,000 (75 wt %-80 wt % of polystyrene and 20 wt %-25 wt % of polyisoprene);
a reactive diluent: 40 g of methyl acrylate.

### Example 26

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 63 g of methacrylic acid;
an additive: 44 g of polystyrene-polyisoprene-polystyrene block copolymer with weight average molecular weight of 60,000 (70 wt %-75 wt % of polystyrene and 25 wt %-30 wt % of polyisoprene);
a reactive diluent: 37 g of ethyl acrylate.

### Example 27

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 63 g of methacrylic acid;
an additive: 44 g of polystyrene-polyisoprene-polystyrene block copolymer with weight average molecular weight of 330,000 (70 wt %-75 wt % of polystyrene and 25 wt %-30 wt % of polyisoprene);
a reactive diluent: 37 g of ethyl acrylate.

### Example 28

A display module of the present example includes 650 μm of a cover plate, 150 μm of an OCA optical adhesive layer, 100 μm of a polarizer, 40 μm of a screen body, 25 μm of a functional layer, 75 μm of a PET support layer, and 260 μm of a buffer layer which are stacked in sequence.

A method for preparing the functional layer includes the following steps: adding 3 g of a photoinitiator, i.e. 1-hydroxycyclohexyl phenyl ketone to the composition, then coating the system added with the initiator onto a surface of a PET substrate and performing UV illumination, then waiting the system to be cured, to obtain the functional layer.

Components of the above composition in the present example include:
a (methyl) acrylic compound: 55 g polyether acrylic acid;
an additive: 34 g of polystyrene-polyisoprene-polystyrene block copolymer with weight average molecular weight of 250,000 (65 wt %-70 wt % of polystyrene and 30 wt %-35 wt % of polyisoprene);
a reactive diluent: 49 g of methyl acrylate;
an auxiliary agent: 1 g of ethylene glycol and 2 g of polydimethylsiloxane.

### Comparative Examples 1a-4a and 7a

Comparative Examples 1a-4a and 7a correspond to Examples 1a-4a and 7a, respectively, and only differ from the Examples in that the Comparative Examples do not contain the additive.

### Comparative Examples 1b-4b and 7b

Comparative Examples 1b-4b and 7b correspond to Examples 1b-4b and 7b, respectively, and the only differ from the Examples in that the Comparative Examples do not contain the additive.

### Comparative Examples 8-11

Comparative Examples 8-11 correspond to Examples 8-11, respectively, and only differ from the Examples in that the compositions of Comparative Examples do not contain the additive.

### Comparative Example 14

Comparative Example 14 corresponds to the Examples 14, and only differs from the Examples in that the composition of Comparative Example does not contain the additive.

### Comparative Examples 15a, 21a

Comparative Examples 15a and 21a correspond to Examples 15a and 21a respectively, and only differ from the Examples in that the Comparative Examples do not contain the additive.

### Comparative Examples 15b, 21b

The Comparative Examples 15b and 21b correspond to the Examples 15b and 21b, respectively, and only differ from the Examples in that the Comparative Examples do not contain the additive.

### Comparative Example 22

Comparative Example 22 corresponds to Example 22, and only differs from the Example in that the composition of Comparative Example does not contain the additive.

### Comparative Example 28

Comparative Example 28 corresponds to Example 28, and only differs from the Example in that the composition of Comparative Example does not contain the additive.

Test Experiment

1. Dielectric Constant Detection

The dielectric constants of the compositions in the above Examples 1a-7a, 15a-21a and Comparative Examples 1a-4a, 7a, 15a, and 21a and of the functional layers in Examples 1b-7b, 15b-21b and Comparative Examples 1b-4b, 7b, 15b, 21b are measured by a LCR tester, and the specific results are shown in Table 1.

2. Acid Value Detection

Compositions or functional layers in some Examples 1a-7a, 15a-21a, 1b-7b, 15b-21b and Comparative Examples 1a-4a, 7a, 15a, 21a, 1b-4b, 7b, 15b, 21b are taken and dissolved with ethanol, then a phenolphthalein indicator is added to obtain samples to be tested. Each sample to be tested is titrated with a potassium hydroxide solution until the color of the sample turns pale pink and does not disappear after shaking, then a volume of consumed potassium hydroxide solution is recorded, and the carboxyl content in the composition of the sample to be tested is calculated and labeled by an acid value (the acid value indicates the mass of potassium hydroxide (mg) used to neutralize carboxyl groups in 100 g of the composition or functional layer). The results are shown in Table 1.

3. Hydroxyl Value Detection

Compositions or functional layers in some Examples 1a-7a, 15a-21a, 1b-7b, 15b-21b and Comparative Examples 1a-4a, 7a, 15a, 21a, 1b-4b, 7b, 15b, 21b are taken and dissolved with ethanol, then 5 mL of an anhydrous pyridine solution having phthalic anhydride (42 g of phthalic anhydride is dissolved in 300 mL of anhydrous pyridine), and a phenolphthalein indicator are added to each gram of the compositions or functional layers to obtain samples to be tested. Each sample to be tested is titrated with a potassium hydroxide solution until the color of the sample turns pale pink and does not disappear after shaking, then a volume of consumed potassium hydroxide solution is recorded, and the hydroxyl content in the composition of the sample to be tested is calculated according to the amounts of phthalic anhydride and potassium hydroxide and labeled by a hydroxyl value (the hydroxyl value indicates the mass of KOH (mg) with the same mole as hydroxyl groups in 100 g of the composition or functional layer). The results are shown in Table 1.

4. Storage Modulus and Adhesion Force Detection

1) Compositions or functional layers in some Examples 1a-7a, 15a-21a, 1b-7b, 15b-21b and Comparative Examples 1a-4a, 7a, 15a, 21a, 1b-4b, 7b, 15b, 21b are taken and made into 1 mm of samples, the storage moduli of which are measured using DMA (Dynamic Thermomechanical Analyzer) under a rotation mode. The results are shown in Table 1.

2) The adhesion force of the compositions or functional layers in Examples 1a-7a, 15a-21a, 1b-7b, 15b-21b and Comparative Examples 1a-4a, 7a, 15a, 21a, 1b-4b, 7b, 15b, 21b are tested with reference to ASTM D3330 test standard. The results are shown in Table 1.

5. Copper Bar Friction Test

The brightness and chromaticity data of the display modules in Examples 8-14, 22-28 and Comparative Examples 8-11, 14, 22 and 28 are tested at different gray scales. Then, the display modules are fixed on a support platform for copper bar line marking, and the friction pressure is set to 1N and the friction velocity is 100 mm/s, and the copper bar line marking equipment is operated. The brightness and chromaticity data after the line has been marked for 24 hours is tested.

If the chromaticity difference and brightness difference before and after the copper bar friction are less than 0.05, and at the same time the edge of the screen body does not appear green when the display module is lit, the test is passed; if at least one of the chromaticity difference and brightness difference before and after the copper bar friction is greater than 0.05, or the edge of the screen body appears green when the display module is lit, the test is not passed. The results are shown in Table 2.

TABLE 1

| | Dielectric | Acid | Hydroxyl | Storage | Adhesion |
|---|---|---|---|---|---|
| | constant | value | value | modulus | force |
| Example 1a | 2.8 | 1.6 | 3.6 | 120 kPa | 1355 gf |
| Comparative | 3.5 | 2.5 | 4.0 | 110 kPa | 1257 gf |
| Example 1a | | | | | |
| Example 1b | 2.0 | 1.4 | 3.0 | 164 kPa | 1692 gf |
| Comparative | 3.2 | 2.3 | 3.9 | 161 kPa | 1504 gf |
| Example 1b | | | | | |
| Example 2a | 2.9 | 1.7 | 3.7 | 100 kPa | 1450 gf |
| Comparative | 3.4 | 2.6 | 4.1 | 103 kPa | 1343 gf |
| Example 2a | | | | | |
| Example 2b | 1.7 | 1.3 | 2.9 | 178 kPa | 1862 gf |
| Comparative | 3.1 | 2.2 | 3.8 | 169 kPa | 1799 gf |
| Example 2b | | | | | |
| Example 3a | 2.9 | 1.8 | 3.6 | 130 kPa | 1420 gf |
| Comparative | 3.4 | 2.5 | 4.2 | 110 kPa | 1243 gf |
| Example 3a | | | | | |
| Example 3b | 2.0 | 1.2 | 3.0 | 168 kPa | 1786 gf |
| Comparative | 3.2 | 2.1 | 4.1 | 180 kPa | 1695 gf |
| Example 3b | | | | | |
| Example 4a | 2.9 | 1.7 | 3.8 | 123 kPa | 1465 gf |
| Comparative | 3.5 | 2.6 | 4.3 | 110 kPa | 1248 gf |
| Example 4a | | | | | |
| Example 4b | 1.9 | 1.3 | 2.8 | 167 kPa | 1964 gf |
| Comparative | 3.4 | 2.1 | 4.1 | 130 kPa | 1534 gf |
| Example 4b | | | | | |
| Example 5a | 3.0 | 1.9 | 3.9 | 100 kPa | 1267 gf |
| Example 5b | 2.6 | 1.8 | 3.8 | 142 kPa | 1589 gf |
| Example 6a | 3.1 | 2.0 | 3.8 | 130 kPa | 1364 gf |
| Example 6b | 2.5 | 1.9 | 3.7 | 180 kPa | 1519 gf |
| Example 7a | 3.0 | 2.0 | 3.7 | 133 kPa | 1387 gf |
| Comparative | 3.4 | 2.1 | 3.9 | 120 kPa | 1294 gf |
| Example 7a | | | | | |
| Example 7b | 2.7 | 1.8 | 3.4 | 160 kPa | 1599 gf |
| Comparative | 3.2 | 1.9 | 3.5 | 152 kpa | 1489 gf |
| Example 7b | | | | | |
| Example 15a | 2.7 | 1.5 | 3.5 | 125 kPa | 1385 gf |
| Comparative | 3.4 | 2.3 | 3.8 | 105 kPa | 1197 gf |
| Example 15a | | | | | |
| Example 15b | 1.8 | 1.3 | 2.9 | 170 kPa | 1672 gf |
| Comparative | 3.1 | 2.1 | 3.7 | 153 kPa | 1404 gf |
| Example 15b | | | | | |
| Example 16a | 2.7 | 1.6 | 3.6 | 104 kPa | 1403 gf |
| Example 16b | 1.6 | 1.2 | 2.7 | 172 kPa | 1892 gf |
| Example 17a | 2.6 | 1.7 | 3.5 | 120 kPa | 1375 gf |
| Example 17b | 1.8 | 1.1 | 3.0 | 167 kPa | 1723 gf |
| Example 18a | 2.7 | 1.5 | 3.5 | 112 kPa | 1425 gf |
| Example 18b | 1.7 | 1.1 | 2.5 | 170 kPa | 1924 gf |
| Example 19a | 2.7 | 1.6 | 3.5 | 115 kPa | 1219 gf |
| Example 19b | 2.4 | 1.6 | 3.5 | 162 kPa | 1545 gf |
| Example 20a | 3.0 | 3.4 | 3.6 | 118 kPa | 1334 gf |
| Example 20b | 2.4 | 1.8 | 3.5 | 168 kPa | 1501 gf |
| Example 21a | 2.8 | 1.7 | 3.4 | 121 kPa | 1301 gf |
| Comparative | 3.1 | 2.0 | 3.5 | 106 kPa | 1247 gf |
| Example 21a | | | | | |
| Example 21b | 2.5 | 1.5 | 3.3 | 162 kPa | 1502 gf |
| Comparative | 3.1 | 1.7 | 3.4 | 146 kpa | 1425 gf |
| Example 21b | | | | | |

TABLE 2

| | Chromaticity | Brightness | Whether the | |
|---|---|---|---|---|
| | difference before | difference before | edge of the | Whether the |
| | and after friction | and after friction | screen is green | test is passed |
| Example 8 | 0.005 | 0.007 | No | Pass |
| Comparative | 0.06 | 0.07 | Yes | Not Pass |
| Example 8 | | | | |
| Example 9 | 0.003 | 0.004 | No | Pass |
| Comparative | 0.05 | 0.07 | Yes | Not Pass |
| Example 9 | | | | |
| Example 10 | 0.01 | 0.01 | No | Pass |
| Comparative | 0.1 | 0.07 | Yes | Not Pass |
| Example 10 | | | | |
| Example 11 | 0.008 | 0.007 | No | Pass |
| Comparative | 0.05 | 0.06 | Yes | Not Pass |
| Example 11 | | | | |
| Example 12 | 0.04 | 0.04 | No | Pass |
| Example 13 | 0.03 | 0.04 | No | Pass |
| Example 14 | 0.02 | 0.01 | No | Pass |
| Comparative | 0.06 | 0.07 | Yes | Not Pass |
| Example 14 | | | | |
| Example 22 | 0.002 | 0.003 | No | Pass |
| Comparative | 0.06 | 0.08 | Yes | Not Pass |
| Example 22 | | | | |
| Example 23 | 0.001 | 0.003 | No | Pass |
| Example 24 | 0.009 | 0.01 | No | Pass |
| Example 25 | 0.004 | 0.006 | No | Pass |
| Example 26 | 0.03 | 0.02 | No | Pass |
| Example 27 | 0.02 | 0.03 | No | Pass |
| Example 28 | 0.01 | 0.008 | No | Pass |
| Comparative | 0.07 | 0.09 | Yes | Not Pass |
| Example 28 | | | | |

According to Table 1 and Table 2, the compositions in the Examples of the present application have a low dielectric constant, and the performance of inhibiting the green screen phenomenon of the display module is more prominent, especially after the polymer is generated. Although Examples 12 and 13, 26 and 27 can also pass the copper bar friction test, the dielectric constants of these functional layers are still higher than those of Examples 8 and 22. Hence, if the dielectric constant is intended to be further reduced, it can be achieved by controlling the weight average molecular weight of the additive between 100,000 and 300,000.

Finally, it should be explained that the above embodiments are only used to illustrate the technical solutions of the present application, but not to limit the present application. Although the present application has been described in detail with reference to the foregoing embodiments, it should be understood by those skilled in the art that the technical solutions described in the foregoing embodiments can still be modified, or some or all of the technical features can be equivalently replaced, and these modifications or substitutions do not make the essence of the corresponding technical solutions deviate from the scope of the technical solutions of various embodiments of the present application.

What is claimed is:

1. A composition comprising, in parts by mass: 50-70 parts of a (methyl) acrylic compound, 30-50 parts of an additive, 30-50 parts of a reactive diluent, and 0-10 parts of an auxiliary agent; and
the additive comprises at least one of a first polyolefin-polyisoprene-second polyolefin block copolymer and derivative of the first polyolefin-polyisoprene-second polyolefin block copolymer.

2. The composition according to claim 1, wherein the additive has a weight average molecular weight of 100,000-300,000.

3. The composition according to claim 1, wherein the additive comprises at least one of a polystyrene-polyisoprene-polystyrene block copolymer, derivative of the polystyrene-polyisoprene-polystyrene block copolymer, a polyethylene-polyisoprene-polyethylene block copolymer, derivative of the polyethylene-polyisoprene-polyethylene block copolymer, a polypropylene-polyisoprene-polyethylene block copolymer and derivative of the polypropylene-polyisoprene-polyethylene block copolymer.

4. The composition according to claim 3, wherein the additive is at least one of the polystyrene-polyisoprene-polystyrene block copolymer and derivative of the polystyrene-polyisoprene-polystyrene block copolymer, wherein a polystyrene segment is 60 wt %-85 wt % and a polyisoprene segment is 15 wt %-40 wt %.

5. The composition according to claim 1, wherein the composition further comprises a photoinitiator comprising one or more of 1-hydroxycyclohexyl phenyl ketone, 2-benzyl-2-dimethylamino-1-(4-morpholinophenyl) butanone, 2-benzyl-2-dimethyl-1-(4-morpholinophenyl) butanone, benzophenone, 4-phenylbenzophenone, benzoin diethyl ether, 2-chloro thioxanthone, 2,4-diethyl thioxanthone.

6. The composition according to claim 1, wherein the (methyl) acrylic compound comprises at least one of (methyl) acrylic acid, polyurethane (methyl) acrylic acid, polyester (methyl) acrylic acid, polyether (methyl) acrylic acid, and epoxy (methyl) acrylic acid.

7. The composition according to claim 1, wherein the reactive diluent comprises a (methyl) acrylate compound comprising at least one of (methyl) ethyl acrylate, (methyl) butyl acrylate, (methyl) methyl acrylate, (methyl) hydroxy acrylate, diol (methyl) ethyl acrylate, diol (methyl) butyl acrylate, diol (methyl) methyl acrylate, diol (methyl) hydroxy acrylate, alkoxy (methyl) ethyl acrylate, alkoxy (methyl) butyl acrylate, alkoxy (methyl) methyl acrylate, and (alkoxymethyl) hydroxyl acrylate.

8. The composition according to claim 1, wherein the auxiliary agent comprises one or more of a defoaming agent, a leveling agent, and a polymerization inhibitor.

9. The composition according to claim 8, wherein the defoaming agent is an alcohol compound.

10. The composition according to claim 8, wherein the leveling agent is an organic silicon resin compound.

11. The composition according to claim 8, wherein the polymerization inhibitor comprises at least one of hydroquinone, benzoquinone, p-hydroxyanisole, 2-tert-butylhydroquinone, 2,5-di-tert-butylhydroquinone, and tris (N-nitroso-N-phenylhydroxylamine) aluminum salt.

12. A functional layer, wherein raw material of the functional layer comprises the composition according to claim 1.

13. The functional layer according to claim 12, wherein the functional layer at least comprises a polymer obtained by polymerization of the (methyl) acrylic compound, the additive, and the reactive diluent that are used as monomers.

14. The functional layer according to claim 13, wherein the functional layer has a dielectric constant of 1.5-2.5, an acid value of 0-1.4 and a hydroxyl value of 0-3.9.

15. The functional layer according to claim 14, wherein the functional layer has a dielectric constant of 1.5-2.0, an acid value of 0-1 and a hydroxyl value of 0-3.

16. The functional layer according to claim 13, wherein the functional layer has a storage modulus of 164 kPa-180 kPa and an adhesion force of 1000 gf-2100 gf.

17. The functional layer according to claim 16, wherein the functional layer has a storage modulus of 170 kPa-172 kPa and an adhesion force of 1900 gf-2000 gf.

18. The functional layer according to claim 12, wherein the functional layer is obtained by the following preparation method:
subjecting a raw material system comprising the composition to polymerization.

19. A display module comprising the functional layer according to claim 12.

20. The display module according to claim 19, wherein the display module comprises a display panel and a support layer located at a non-light-emitting side of the display panel, and the functional layer is located between the display panel and the support layer.
